(19) United States
(12) Patent Application Publication
(10) Pub. No.: US 2026/0231562 A1
(43) Pub. Date: Aug. 6, 2026

(54) CASCADED SUPERLATTICE NARROWBAND LED

(71) Applicant: UNIVERSITY OF IOWA RESEARCH FOUNDATION, Iowa City, IA (US)

(72) Inventors: John Prineas, Iowa City, IA (US); David Alexander Montealegre, Champaign, IL (US)

(73) Assignee: UNIVERSITY OF IOWA RESEARCH FOUNDATION, Iowa City, IA (US)

(21) Appl. No.: 19/152,186

(22) PCT Filed: Jan. 30, 2024
(86) PCT No.: PCT/US2024/013561

§ 371 Date: Jul. 30, 2025

Related U.S. Application Data
(60) Provisional application No. 63/442,033, filed on Jan. 30, 2023.

(51) Int. Cl. H10H 20/812; H10H 20/813; H10H 20/814; H10H 20/822; H10H 20/832

(52) U.S. Cl. CPC H10H 20/812; H10H 20/8131; H10H 20/8142; H10H 20/822; H10H 20/835

(57) ABSTRACT

An apparatus for generating infrared radiation is disclosed. The apparatus is a light emitting diode including a resonant cavity and a cascaded superlattice included in the resonant cavity.

### CROSS-REFERENCE TO RELATED APPLICATION

This application claims priority to U.S. Provisional Application No. 63/442,033 that was filed on Jan. 30, 2023. The entire content of the application referenced above is hereby incorporated by reference herein.

### STATEMENT REGARDING FEDERALLY SPONSORED RESEARCH

This invention was made with government support under FA248717P0136 awarded by Department of the Air Force and W900KK20C0008 awarded by Department of Defense. The government has certain rights in the invention.

### FIELD

The present disclosure describes a cascaded superlattice narrowband LED.

### BACKGROUND

The present disclosure relates to an apparatus for generating electromagnetic radiation in a narrow frequency band from a light emitting diode. Generally, paired distributed Bragg reflectors (DBRs) are used in similar devices. DBRs are relatively thick, which adds extra time and cost to fabrication of the devices and complicates the planarization of the device contacts. Currently, emitters in the infrared region of the electromagnetic spectrum used to generate a narrow frequency band from a light emitting diode are inefficient. For applications requiring two wavelengths, two discrete devices are required, which increases the cost of the application. For these and other reasons there is a need for aspects of the disclosed embodiments that address these and other disadvantages and concerns associated with generating narrowband electromagnetic radiation.

### BRIEF DESCRIPTION OF THE DRAWINGS

FIG. 1A shows an illustration of a stack for a cavity light emitting diode (LED) in accordance with some embodiments of the present disclosure;

FIG. 1B shows a stack for a non-cavity LED in accordance with some embodiments of the present disclosure;

FIG. 1C shows a detailed stack illustration for the superlattice portion of the stacks shown in FIG. 1A and FIG. 1B in accordance with some embodiments of the present disclosure;

FIG. 2A shows a graph of current dependent output of the cavity LED and current dependent output of a non-cavity LED at 77K in accordance with some embodiments of the present disclosure;

FIG. 2B shows a graph of peak of emission of the cavity and non-cavity LED versus current density in accordance with some embodiments of the present disclosure;

FIG. 3 shows a radiance-current density plot for a resonant cavity LED versus a non-cavity LED at 77K in accordance with some embodiments of the present disclosure;

FIG. 4 shows a spectral radiance-current density plot for a resonant cavity LED versus a non-cavity LED at 77K in accordance with some embodiments of the present disclosure;

FIG. 5A shows a temperature dependent emission spectra for a cavity LED versus a non-cavity LED in accordance with some embodiments of the present disclosure;

FIG. 5B shows a plot of a spectral peak of a cavity LED and a non-cavity LED versus temperature in accordance with some embodiments of the present disclosure;

FIG. 6 shows a growth stack schematic for a cavity LED with a second non-cavity emission peak that is independently controllable in accordance with some embodiments of the present disclosure;

FIG. 7A shows an illustration of a three contact layout for a multispectral cavity LED in accordance with some embodiments of the present disclosure;

FIG. 7B shows an illustration of a two contact layout for a single color LED in accordance with some embodiments of the present disclosure;

FIG. 8 shows a comparison of a methane absorption spectrum for a non-cavity LED and a cavity LED in accordance with some embodiments of the present disclosure;

FIG. 9 shows an illustration of a light emitting diode including a resonant cavity and a cascaded superlattice included in the resonant cavity in accordance with some embodiments of the present disclosure;

FIG. 10 shows an illustration of a gas sensor including the light emitting diode in accordance with some embodiments of the present disclosure;

FIG. 11 shows an illustration of an apparatus including an array of light emitting devices formed on a substrate in accordance with some embodiments of the present disclosure; and

FIG. 12 shows an illustration of a light emitting diode stack including the capability to generate a second non-cavity peak that is independently controllable in accordance with some embodiments of the present disclosure.

FIG. 13 shows a graph of simulated Purcell factor and extraction efficiency for a single dipole in a semi-cavity versus the distance of the dipole from the reflector in accordance with some embodiments of the present disclosure.

FIG. 14 shows an illustration of a stack diagram of the simulated device, using a single emission region per antinode. The pattern of emission regions may be repeated to get the total desired number of simulated regions, which was 8 for most of the initial theoretical work in accordance with some embodiments of the present disclosure. The E-field squared profile is shown alongside the stack to show centering of the emission region on anti-nodes.

FIG. 15 shows an illustration of a plot of extraction efficiency versus the distance between the mirror and the interface of the first emission region in accordance with some embodiments of the present disclosure. This is an 8-stage simulation with a single emission region per antinode.

FIG. 16 shows a graph of Simulated EQE versus stage thickness for selected current densities with (solid lines) and without (dashed lines) microcavity enhancement (but still including trivial reflected power from the one mirror, assumed to be 93% reflecting) at the design wavelength in accordance with some embodiments of the present disclosure. The simulated configuration is a six-stage device, with a single stage per antinode, at room temperature.

FIG. 17 shows a heatmap of current density versus stage thickness, with EQE as the color on the contours, for a 6 stage device at room temperature in accordance with some embodiments of the present disclosure.

FIG. 18 shows an illustration of the stack diagram of a 120 nm emission region sample in accordance with some embodiments of the present disclosure. The difference between the 120 nm sample and other samples is the number of emission regions grouped within the antinode.

FIG. 19 shows an illustration of the stack diagram of a full cavity device with six emission regions, with the DBR serving as the bottom reflector to confine the cavity in accordance with some embodiments of the present disclosure. The baseline device was identical except with no bottom DBR.

FIG. 20 shows experimental WPE calculations plotted versus cap thickness, or distance of the first emission region from the reflective contact (left) in accordance with some embodiments of the present disclosure. The WPE axis for all four plots spans the same range, though the values are shifted. These are compared to theoretical extraction efficiency plots versus cap thickness (right) at the design wavelength in accordance with some embodiments of the present disclosure. All plots are for eight stage devices at room temperature.

FIG. 21A shows a graph of wavelength averaged EQE versus current density for the four fabricated device designs in accordance with some embodiments of the present disclosure.

FIG. 21B shows the analogous experimental plot of FIG. 21A, WPE versus current density for these selected emission region thicknesses, in accordance with some embodiments of the present disclosure. Both the theoretical (FIG. 21A) and experimental plot (FIG. 21B) are for devices measured at room temperature.

FIG. 22A shows a plot of radiance versus current density of the 280 nm emission region sample at room temperature in accordance with some embodiments of the present disclosure.

FIG. 22 B shows a plot of current density versus bias of the 280 nm emission region sample at room temperature in accordance with some embodiments of the present disclosure. The inset of shows the EL spectrum of these samples. Radiance may be converted to output power by multiplying it by the device area times pi.

FIG. 23A shows a EQE heatmaps of the baseline in accordance with some embodiments of the present disclosure.

FIG. 23B shows a EQE heatmap of the full cavity modeled at 77 K for the resonant wavelength in accordance with some embodiments of the present disclosure. The full cavity has a peak EQE approximately 10 times that of the baseline.

FIG. 24 shows a graph of radiance versus current density for the baseline (semi-cavity) and RCLED (full cavity) devices at 77K in accordance with some embodiments of the present disclosure. The baseline overall performs slightly better than the RCLED. Radiance may be converted to output power by multiplying it by the device area times pi.

FIG. 25 shows a graph of peak spectral radiance versus current density at the resonant wavelength of the RCLED at 77K in accordance with some embodiments of the present disclosure. Note the 4 to 5 times increase over the baseline.

FIG. 26 shows a graph of electroluminescence normalized by area versus wavelength at 77K, showing the RCLED is enhanced at the design wavelength where the DBR reflection peaks, but suppressed at other wavelengths in accordance with some embodiments of the present disclosure.

FIG. 27A and FIG. 27B illustrate dependence of the peak position of the RCLED versus the baseline half-cavity on temperature and current density, respectively, in accordance with some embodiments of the present disclosure.

FIG. 28 shows the temperature dependence of the peak spectral radiance in accordance with some embodiments of the present disclosure. The inset shows the temperature dependent emission spectrum.

### DESCRIPTION

Reference will now be made in detail to the embodiments implemented according to this disclosure, the examples of which are illustrated in the accompanying drawings.

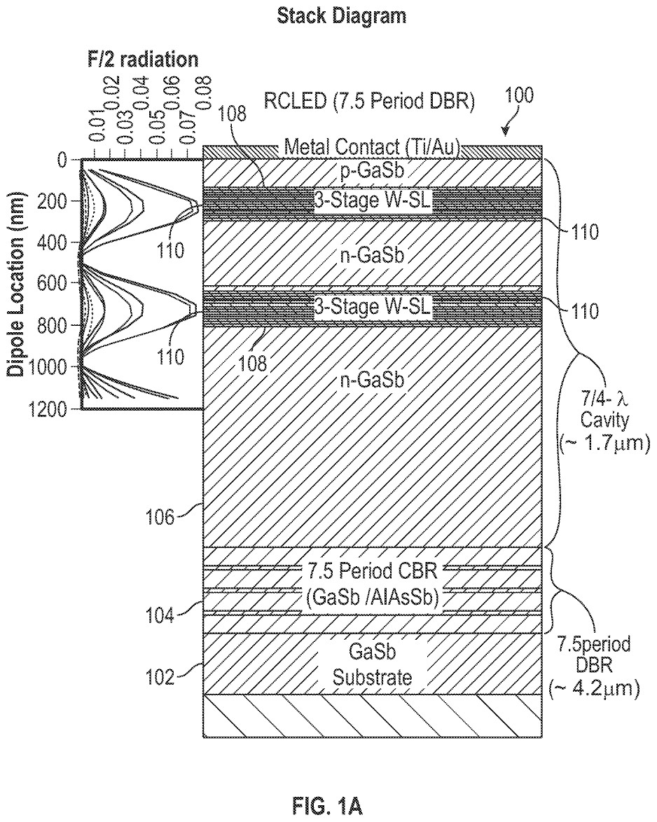

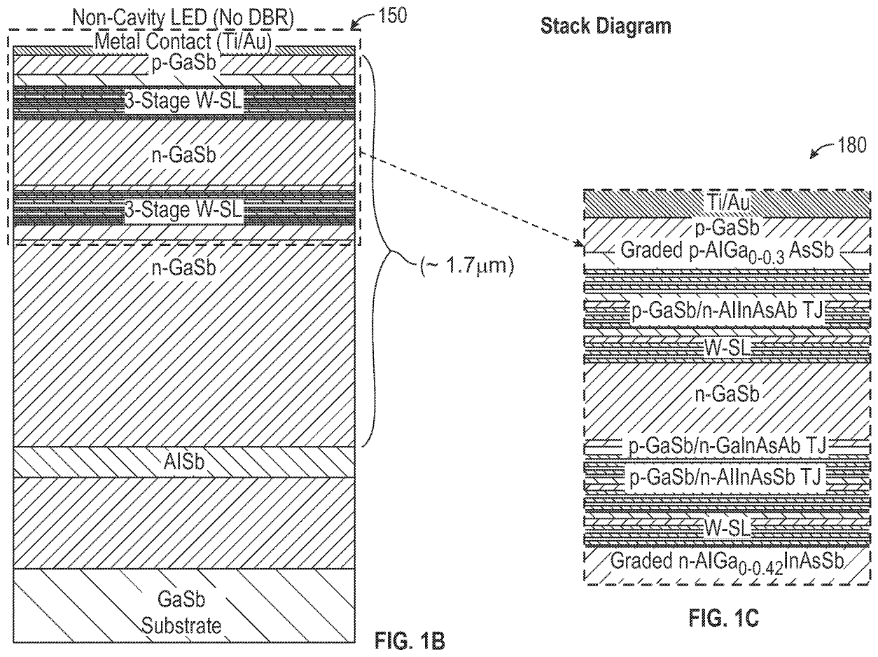

The following disclosure describes a light emitting diode designed for emitting light in a narrowed waveband in the mid-infrared through placement of a cascaded superlattice in a single mode resonant cavity. There are many advantages to this approach to producing infrared electromagnetic radiation. The comparison of cavity and non-cavity devices, as shown in FIGS. 1-8 and described below illustrate a few of the advantages. For example, the enhanced mode density normal to the mirrors leads to higher spectral radiance for a cavity LED than a non-cavity LED. This is useful whenever trying to channel more optical power into a narrower wavelength band. And, as a further example, the cavity resonance spectral position for a cavity LED is less sensitive to temperature or current injection changes than the spectral position of a non-cavity LED, making it more spectrally stable. Finally, the narrower spectrum obviates the need for an external optical filter to narrow LED output, reducing cost and complexity for applications that require a narrow LED output.

FIG. 1A shows an illustration of a stack for a cavity light emitting diode (LED) 100 in accordance with some embodiments of the present disclosure. The device heterostructure shown in FIG. 1A includes a substrate 102, a bottom DBR 104, an n-type cathode 106 inside the cavity, and W-superlattices 108 separated by semi-metallic tunnel junctions 110 that are positioned at the antinodes of the standing electric field. The example structure shown in FIG. 1A generates about a 40 nm emission peak width centered at about 3.6 μm through the use of a 7/4 lambda cavity (single mode, accounting for the boundary conditions imposed by the two mirrors) with a 7.5 period GaSb/AlSbAs bottom DBR. W-superlattices are about 80 nm thick and consist of 6.6 ml AlSbAs (0.27)/5.7 ml InAs/8.5 ml In (0.3) GaSb/InAs in a single period separated by n-Al (0.20) InSbAs (73%)/p-GaSb tunnel junctions of a width of between about 10 nm and about 15 nm. These layers are all lattice-matched to GaSb. FIG. 1B shows a stack for a non-cavity LED in accordance with some embodiments of the present disclosure. FIG. 1C shows a detailed stack illustration for the superlattice portion of the stacks shown in FIG. 1A and FIG. 1B in accordance with some embodiments of the present disclosure.

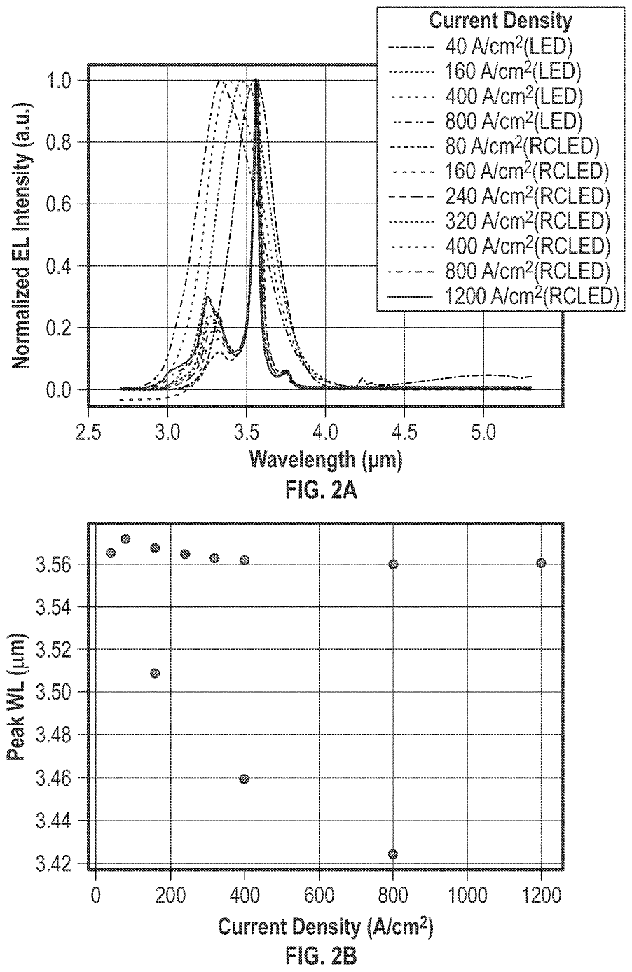

FIG. 2 shows a graph of current dependent output of a cavity LED at 77K, current dependent output of a non-cavity LED at 77K, and peak emission of a cavity LED (decaying curve for dots at 3.56 and above) and peak emission of a non-cavity LED (decaying curve for dots starting above 3.56 and below) in accordance with some embodiments of the present disclosure. FIG. 2 shows the current stability of the infrared resonant cavity light emitting diode (IRCLED) emission peak is much better than that of the non-cavity infrared light emitting diode (IRLED).

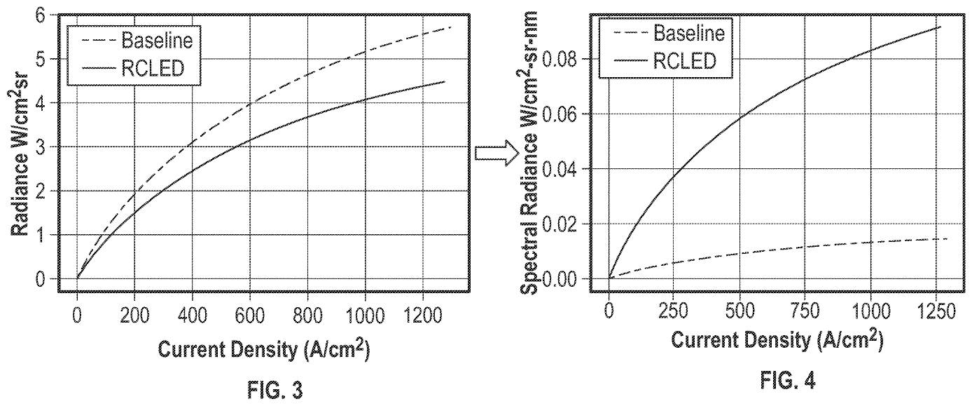

FIG. 3 shows a radiance-current density plot for a resonant cavity LED versus a non-cavity LED at 77K in accordance with some embodiments of the present disclosure. FIG. 4 shows a spectral radiance-current density plot for a resonant cavity LED versus a non-cavity LED at 77K in accordance with some embodiments of the present disclosure. Thus, FIG. 3 and FIG. 4 show curves for an IRCLED versus an otherwise identical IRLED. While the IRLED and IRCLED have similar radiances, the IRCLED has much higher spectral radiance.

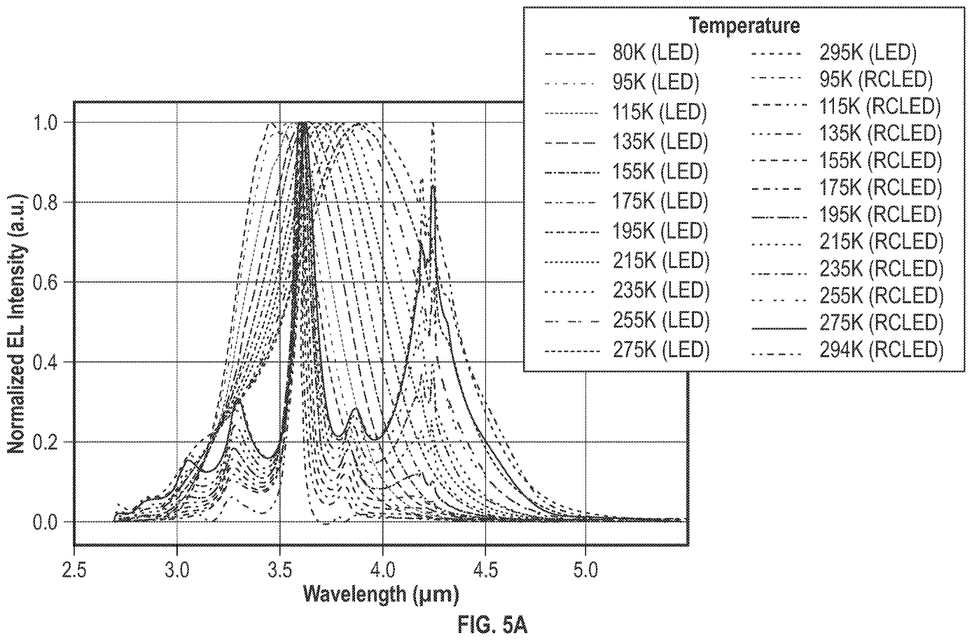

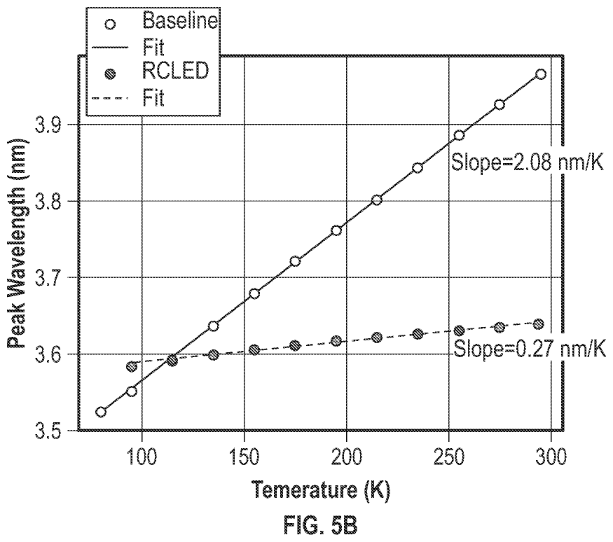

FIG. 5A shows a temperature dependent emission spectra for a cavity LED (solid lines) versus a non-cavity LED (dashed lines) in accordance with some embodiments of the present disclosure. FIG. 5B shows a plot of a spectral peak of a cavity LED and a non-cavity LED versus temperature in accordance with some embodiments of the present disclosure. FIG. 5A and FIG. 5B show the thermal and current stability of the IRCLED emission peak is much better than that of the IRLED.

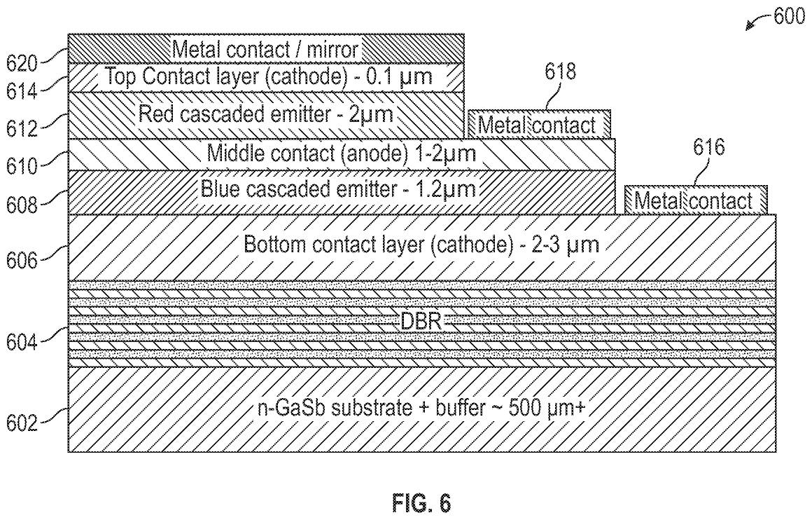

FIG. 6 shows a growth stack schematic 600 for a cavity LED with a second non-cavity emission peak that is independently controllable in accordance with some embodiments of the present disclosure. The growth stack schematic 600 includes an n-GaSb substrate+buffer (~500 μm+) 602, DBR 604, bottom contact layer (cathode) (2-3 μm) 606, blue cascaded emitter (1.2 μm) 608, middle contact (anode) (1-2 μm) 610, red cascaded emitter (2 μm) 612, top contact layer (cathode) (0.1 μm) 614, metal contact 616, metal contact 618, and metal contact/mirror 620.

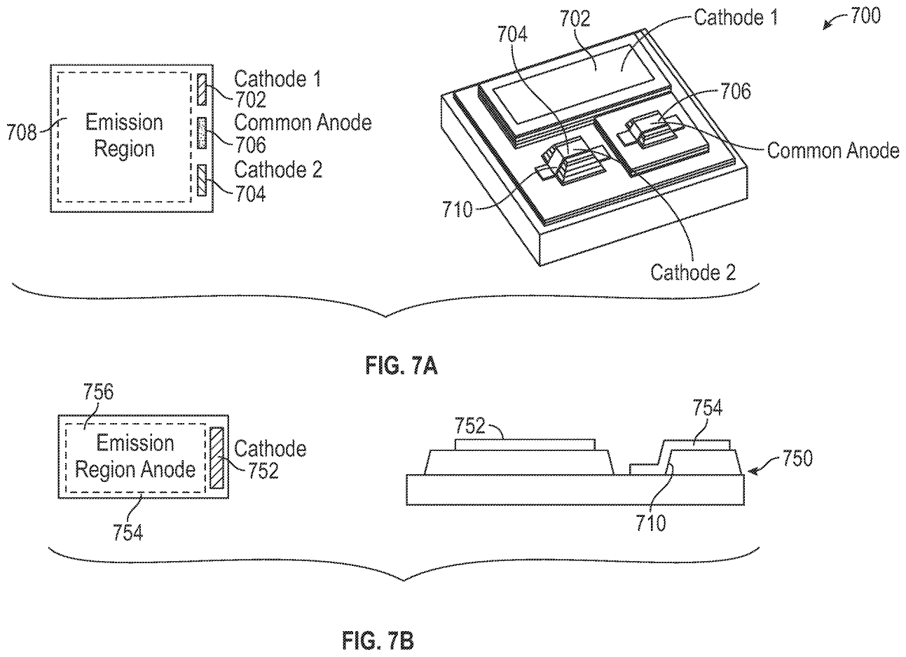

FIG. 7A shows an illustration of a three contact layout 700 for a multispectral cavity LED in accordance with some embodiments of the present disclosure. The three contact layout 700 includes a cathode 1 702, cathode 2 704, common anode 706, and emission region 708. FIG. 7B shows an illustration of a two contact layout 750 for a single color LED in accordance with some embodiments of the present disclosure. The two contact layout 750 includes a cathode 752, an anode 754, and an emission region 756. Through the use of straps 710 down mesa sidewalls, all three contacts are planarized for convenient flip chipping. A second emission peak can be created outside the DBR in two ways: First, one or more of the W-superlattices can be tuned to a different wavelength by alterations to the thickness of the layers or the composition of the layers. In this case, current injection into the device will simultaneously light up emission at the Fabry-Perot and the second wavelength outside the Fabry-Perot. Second, a thicker, multi-mode cavity can be created with a third metal contact for independent control of the second emission peak. An example heterostructure for creating such a three-contact device is shown in FIG. 6. An n-type contact layer is positioned in the middle of the cavity between two W-superlattice types: one resonant with the Fabry-Perot, the other outside the DBR reflection band. An n-type anode is used for the bottom contact layer to reduce free carrier absorption in the cavity. Alternatively, the same strategies can be used in a reverse polarity device (cathode-anode-cathode or anode-cathode-anode).

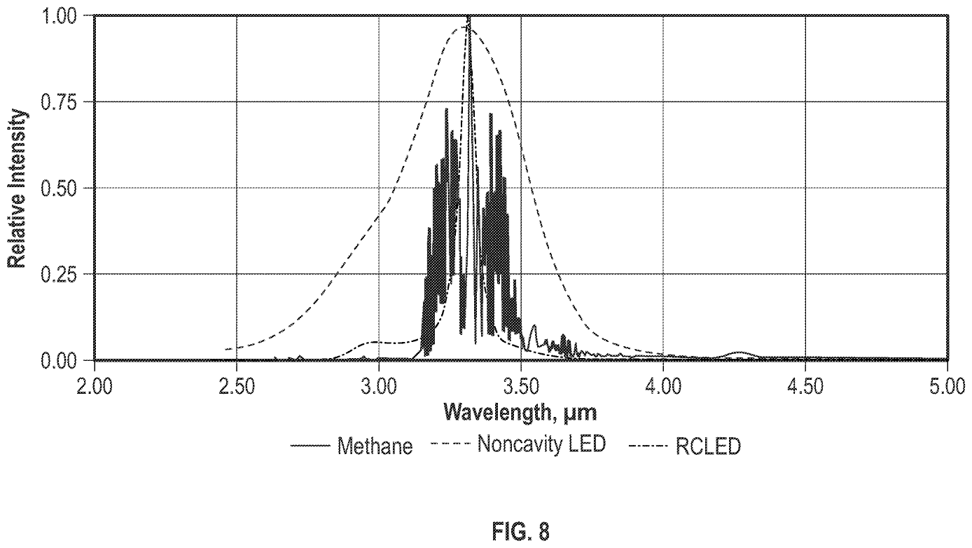

FIG. 8 shows a comparison of a methane absorption spectrum for a non-cavity LED and a cavity LED in accordance with some embodiments of the present disclosure. The device described could be useful in an optical gas sensor. Narrowband LEDs are useful in gas sensing for several reasons. First, the narrower spectrum obviates the need for an external optical filter to narrow LED output, reducing the cost and complexity of the device. Second, the enhanced mode density normal to the mirrors for a cavity LED leads to higher spectral radiance than a non-cavity LED. This is useful whenever trying to channel more optical power into a narrower wavelength band. Third, the cavity resonance spectral position in a cavity LED is less sensitive to temperature or current injection changes than the spectral position of a non-cavity LED, making it more spectrally stable. As shown in FIG. 8, a narrowed, more stable emission line leads to better overlap with individual gas absorption lines, which leads to better gas selectivity and less chance for false readings from overlap with other gas absorption lines. Increased spectral radiance and higher absorption due to improved spectral overlap leads to higher sensor sensitivity. The reference wavelength outside the cavity can be used for sensor calibration. Because it come from the same LED as the signal emission, the reference is co-linear and auto aligned to the sensor detector.

The devices described could also be used in a thermal scene generator. A thermal scene generator uses an array of emitters to create a scene with correct thermal signatures for test and evaluation of thermal cameras. The narrowed emission and increased stability of the Fabry-Perot emission allows the emission to occur in a defined narrowed waveband.

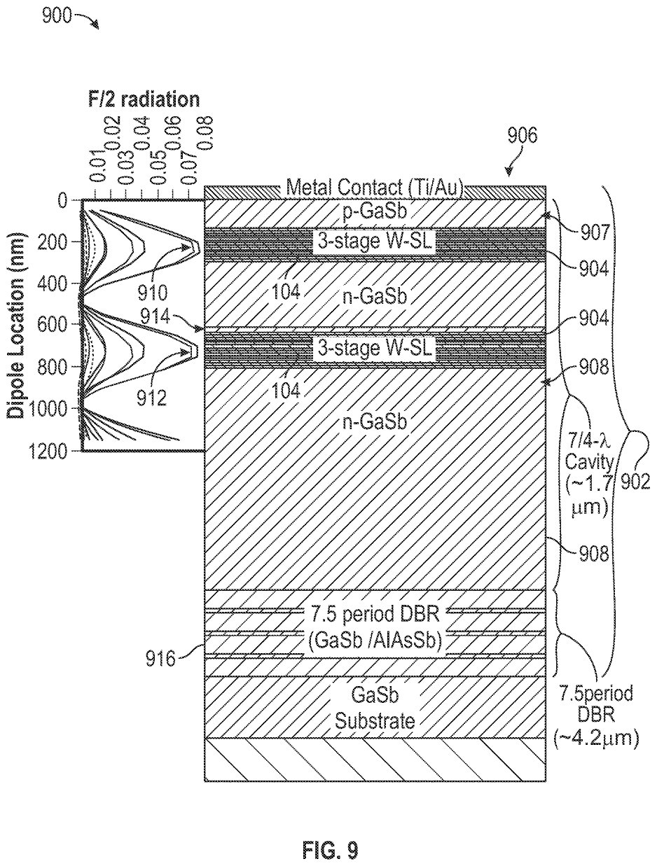

FIG. 9 shows an illustration of a light emitting diode 900 including a resonant cavity 902 and a cascaded superlattice 904 included in the resonant cavity 902 in accordance with some embodiments of the present disclosure. In operation, the light emitting diode 900 emits a narrowed waveband in the mid-infrared region of the electromagnetic spectrum. In some embodiments, the light emitting diode 900 includes a sacrificial mesa having an angled sidewall, as shown in FIG. 7. The resonant cavity 902 is a combination of optical elements that forms a cavity resonator for electromagnetic waves, such as waves in the infrared portion of the electromagnetic spectrum. In some embodiments, the resonant cavity 902 is a single mode resonant cavity. In some embodiments, the resonant cavity 902 has a low number of modes. The cascaded superlattice 904 is a semiconductor device that emits in the mid-infrared to the far-infrared portion of the electromagnetic spectrum.

In some embodiments, the light emitting diode 900 includes a mirror 906 that also functions as a top contact for the light emitting diode 900. Combining two functions in the mirror 906 simplifies fabrication and reduces cost of the light emitting diode 900. Also, by combining functions and avoiding the use of a second distributed Bragg reflector, current does not have to be injected through a second distributed Bragg reflector (DBR), which reduces device resistance and ohmic loss. In some embodiments, the mirror 906 is a metal mirror and includes Ti/Au. In some embodiments, the mirror 906 is a metal mirror and includes TiPtAu. In some embodiments, the mirror 906 is a broadband metal mirror. In some embodiments, the mirror 906 contacts a thin p-type layer 907 and substantially minimizes free carrier absorption.

FIG. 9 also includes an n-type bottom contact 908 that is included inside the resonant cavity 902. Including the n-type bottom contact 908 inside the resonant cavity 902 provides a current drain path that does not include a distributed Bragg reflector commonly used in similar devices. Including the n-type bottom contact 908 (cathode) inside the cavity also avoids high free carrier absorption of p-type dopants and resulting optical loss.

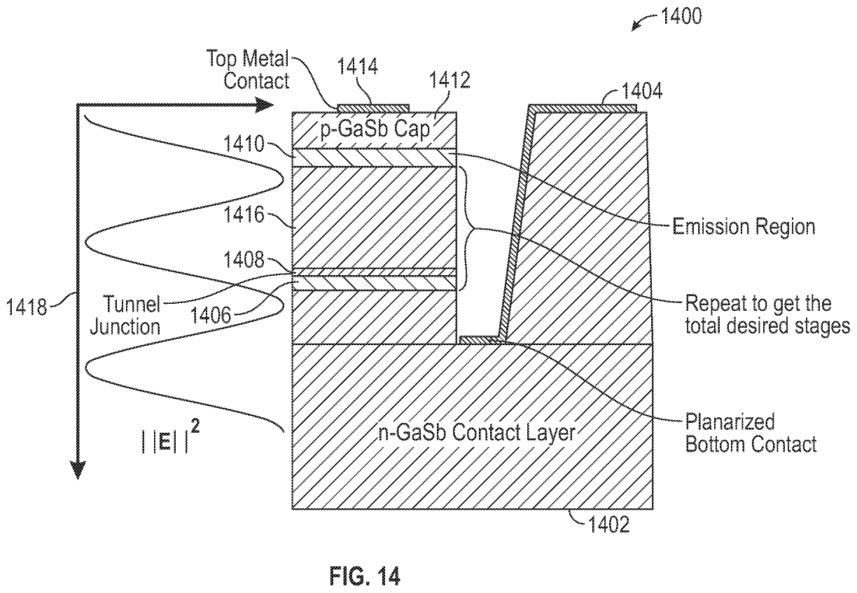

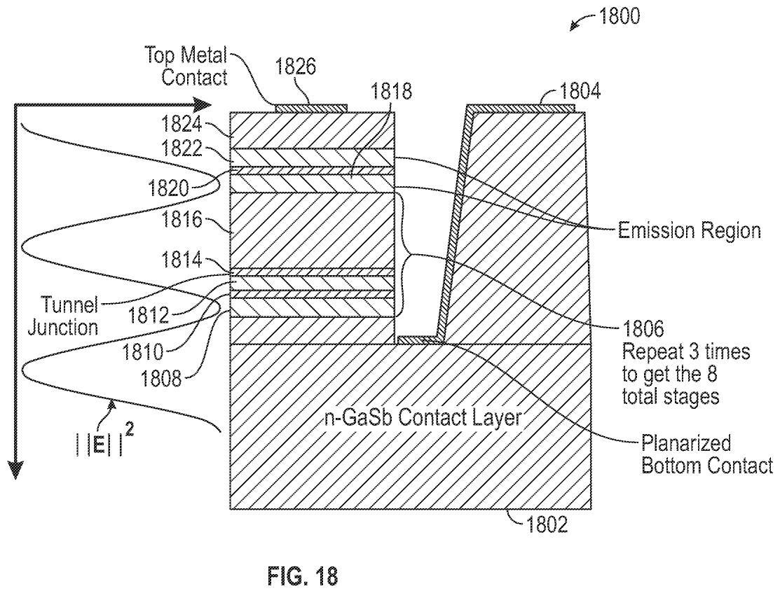

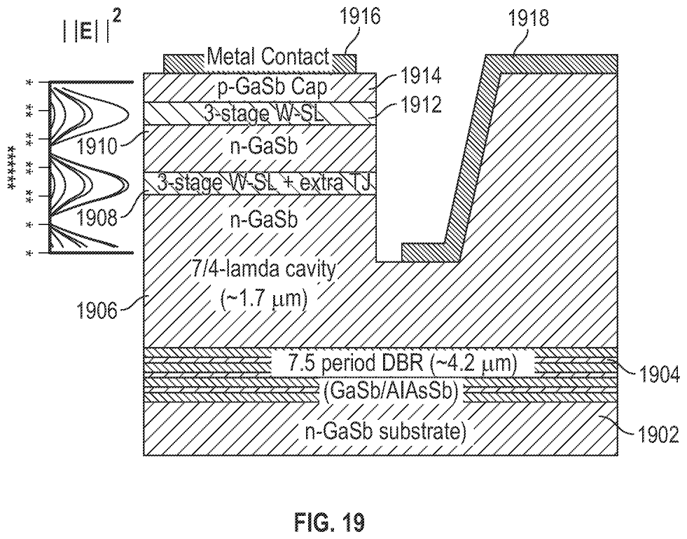

To provide for flip-chip positioning of the light emitting diode 900 when incorporated into a larger system, such as a gas sensing system mounted on a module or board, in some embodiments, the mirror 906 that also functions as a top contact and the bottom metal contact to the bottom contact layer 908 are planarized. Planarization of the contact to bottom contact layer 908 is achieved by routing a metal strap (see FIG. 7, FIG. 14, FIG. 18, and FIG. 19) from the bottom contact layer 908 to a position above the bottom contact layer that is in the same plane as the mirror 906. In some embodiments, the metal contact to the n-type bottom contact layer 908 is Pd/Ge/Ti/Pt/Au contact. Having the top mirror/contact 906 and the bottom contact to bottom contact layer 908 in the same plane simplifies the process and reduces the cost of mounting the light emitting diode 900 on a module or board. Planarized contacts enable easy flip chipping of the light emitting diode 900 to a header or incorporating the light emitting diode 900 into a sensor through reflow.

The light emitting diode 900 is not limited to a particular type of cascaded superlattice 904. In some embodiment, the cascaded superlattice 904 is a cascaded W-superlattice. A W-superlattice is a type of symmetric superlattice that introduces a barrier layer to the superlattice stack to balance strain and enhance spatial wavefunction overlap where the higher energy offset semiconductor is repeated on either side of the lower energy offset semiconductor.

Cascaded W-superlattices provide high quantum efficiency emitters in the infrared region of the electromagnetic spectrum. Cascaded W-superlattices, suitable for use in the fabrication of the light emitting diode 900 are described in U.S. patent publication titled CASCADED SUPERLATTICE LED SYSTEM having document identifier US20200013923 A1 and having a publication date of 2020 Jan. 9. US20200013923 A1 is incorporated by reference, herein, in its entirety. In some embodiments, the cascaded superlattice 904 includes layers lattice matched to GaSb. In some embodiments, the W-superlattice includes AlSb/InAs/InGaSb/InAs. The light emitting diode 900 is also not limited to a particular number of cascaded superlattices. As shown in FIG. 900, the light emitting diode 900 includes two cascaded superlattice emission regions having the reference number 904.

As can be seen, in FIG. 9, the resonant cavity 902 includes one or more antinodes, such as antinodes 910 and 912, for example. Each of the one or more antinodes 910 and 912 are regions of maximum amplitude of a standing electromagnetic wave located between adjacent nodes of a standing electromagnetic wave in the resonant cavity 902. In some embodiments, the cascaded superlattice 904 is a cascaded W-superlattice positioned at the antinode 910. The tunnel junction 914 separates two n-type materials. The tunnel junction 914 ensures that an electron exits the bottom cascaded W-superlattice to the next n-GaSb region instead of a hole. In some embodiments, N W-SL emission regions are separated by n−1 TJs within an antinode. There is an n-doped transport region for current between W-SLs at each of the antinodes. After the first grouping of W-SLs in the first antinode, subsequent groupings must end with an extra TJ so that all transport regions can remain n-type. The use of n-type transport regions substantially reduces free carrier absorption in the cavity as compared with p-type transport regions.

A distributed Bragg reflector 916 forms one end of the resonant cavity 902. A distributed Bragg reflector (DBR) is a structure formed from a plurality of layers of alternating materials with different refractive indexes and quarter wave thickness. In some embodiments, the distributed Bragg reflector includes 7.5 periods, includes GaSb/AlAsSb and has a thickness of about 4.2 micrometers.

The light emitting diode 900 emits light in the mid-infrared frequency range. In some embodiments, the light emitting diode 900 emits light in a narrowed waveband in the mid-infrared frequency range. The width of the Fabry-Perot resonance is determined by the number of periods in the DBR: more periods result in a narrower emission line. The Fabry-Perot is centered on the photoluminescence peak to enhance a narrow waveband of the emission while suppressing emission at other wavelengths. The Fabry-Perot is also spectrally centered in the middle of the reflection band of the DBR.

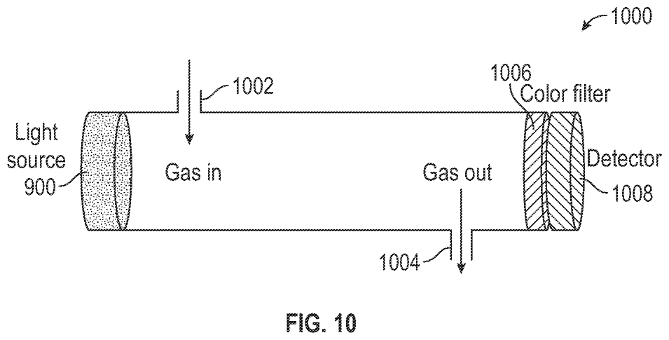

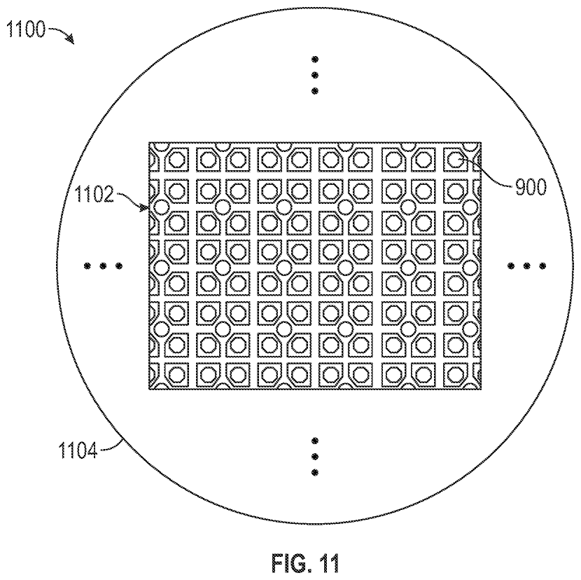

FIG. 10 shows an illustration of a gas sensor 1000 including the light emitting diode 900 I accordance with some embodiments of the present disclosure. In some embodiments, the gas sensor 100 includes a gas input port 1002, a gas output port 1004, a color filter 1006, and a detector 1008. The light emitting diode 900 is useful for gas sensing, where a narrowed, spectrally brighter emission leads to higher sensitivity and selectivity. The light emitting diode 900 is also useful for thermal scene projectors, where emission into a narrow mid-infrared waveband may be desired. In some embodiments the gas sensor which includes the light emitting diode 900 is designed to detect methane.

FIG. 11 shows an apparatus 1100 including an array of light emitting devices 1102 formed on a substrate 1104 in accordance with some embodiments of the present disclosure. At least one of the light emitting devices in the array of light emitting devices 1102 is the light emitting diode 900. In the array of light emitting devices 1102, the light emitting diode 900 includes a contact and the contact is planarized.

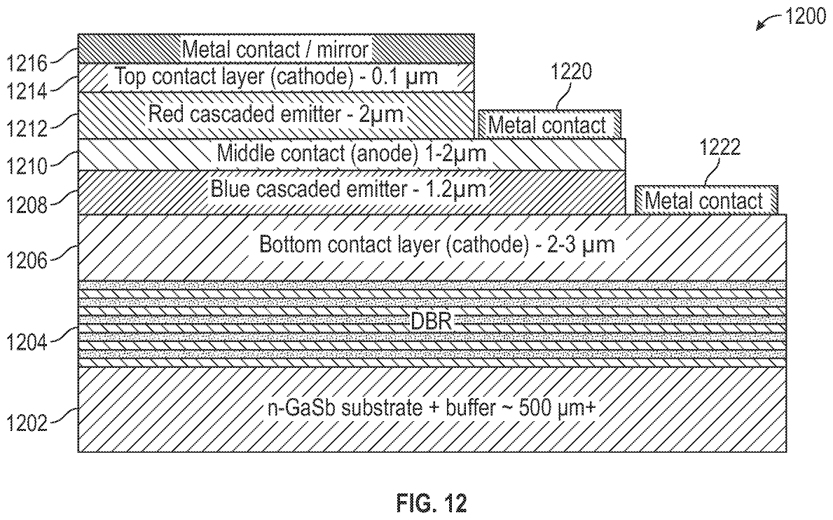

FIG. 12 shows an illustration of a light emitting diode stack 1200 including a second non-cavity peak that is independently controllable in accordance with some embodiments of the present disclosure. The light emitting diode stack 1200 includes an n-GaSb substrate (~500 μm+) 1202, a distributed Bragg reflector 1204 formed on the n-GaSb substrate 1202, a bottom contact layer 1206 (2-3 μm) formed on the distributed Bragg reflector 1204, a first color emitter 1208 (1.2 μm) formed on the bottom contact layer 1206, the first (shorter wavelength) color emitter 1208 comprised of cascaded W-superlattices, a middle contact (anode) (1-2 μm) 1210 formed on the first color emitter 1208, a second (longer wavelength) (2 μm) color emitter 1212 formed on the middle contact 1210, also comprised of cascaded W-superlattices, and a top contact layer (cathode) (0.1 μm) 1214 formed on the second color emitter 1212, and a mirror 1216 that also functions as a top metal contact formed on the second contact layer 1214. The light emitting diode stack 1200 further includes a metal contact 1220 in contact with the middle contact 1210 and a metal contact 1222 in contact with the bottom contact layer 1206. In operation, the light emitting diode stack 1200 incorporates narrowed emission at a wavelength determined by the cavity resonance, and a second wavelength, independently controllable, outside the bandwidth of the DBR, which can be useful as a co-linear reference signal in gas sensing, or a second color in thermal scene projection.

In some embodiments, the light emitting diode stack includes a top, middle, and bottom contact layer, all within the cavity, metal contacts to the contact layers are all planarized, as shown in FIG. 7, in between the contact layers are groups of cascaded W-SLs at antinodes, all the contact layers are n-type, facilitated by an extra TJ after each W-SL grouping at an antinode, and the spectrally narrow color in the cavity may detect a gas; the spectrally wider color non-resonant with the cavity serves as a colinear reference for the sensor.

### Theory

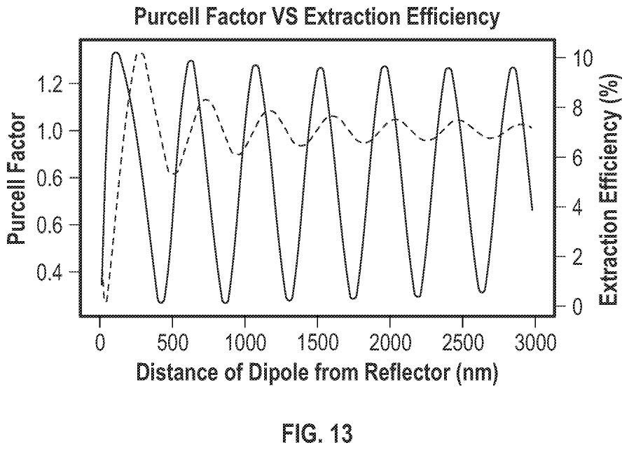

The impact of both the microcavity and Auger recombination on the external quantum efficiency of an LED device is described. The microcavity can enhance the spontaneous emission lifetime of a dipole when placed at the antinodes of the electric field standing wave in a cavity, known as the Purcell effect. The enhancement factor of the angle-integrated emission rate is the Purcell factor, Fp. Additionally, in the vertical direction of a planar microcavity, the dipole couples to a higher density of photonic modes, and an isotropic source emits preferentially in that direction due to Fermi's Golden Rule. Because more of the emitted light then falls within the escape cone of the medium, the extraction of light is enhanced. The Purcell factor, Fp, and the enhanced extraction efficiency η may be calculated using a FDTD Maxwell equation solver, here MEEP. In the simulations, dipoles are assumed to be confined to an in-plane orientation, as is true in superlattices. FIG. 13 shows Fp, and η, defined here as the extraction efficiency of an in-plane dipole as a function of the distance from the mirror:

$$η ( z ) = Pupper hemisphere ( z ) / Psem i \text{-c} avity = Pupper hemisphere ( z ) / FP ( z ) Phomogenous , \qquad ( 1 )$$

where the position dependent extraction efficiency is η(z), Pupper hemisphere (z) is the power emitted into the upper hemisphere air as a function of position, Psemi-cavity is the power emitted by a dipole internally into the semi-cavity in all directions, and Phomogenous is the power emitted by a dipole internally in a homogenous medium. As the distance is increased, the dipole goes in and out of alignment with field antinodes, resulting in oscillating extraction efficiency. Note peaks in the extraction efficiency do not coincide with those of the Purcell factor, because while the former is determined by emission in the forward direction, the latter is integrated over all angles.

In FIG. 14, a stack diagram 1400 of the theoretically simulated device is shown. FIG. 14 includes an n-GaSb contact layer 1402, a planarized bottom contact 1404 in contact with the n-GaSb contact layer 1402, a first emission region 1406 formed on the n-GaSb contact layer 1402, a tunnel junction 1408 is located between the first emission region 1406 and a second emission region 1410, an n-GaSB layer 1416 is located between the first emission region 1406 and the second emission region 1408, a p-GaSb cap layer 1412 formed between the second emission region 1410 and a top metal contact 1414 in contact with the p-GaSB cap layer 1412. This device including the stack 1400 has one emission region per antinode, with the emission region centered at the peak of the antinode. Emission regions 1406 and 1410 include W-superlattices designed for 3.3 μm emission (AlSb0.72As0.28/InAs/In0.30-Ga0.70Sb/InAs thicknesses 5.9/4.1/8.2/4.1 monolayers). The top metal contact 1414 serves as a reflector for the simulations. Thin tunnel junction 1408 and any additional tunnel junctions, which connect emission regions in series rather than in parallel, and spacers, which transport current, separate the emission regions from each other. The spacer is n-doped GaSb layer 1416, while the p-GaSb cap layer 1412, which provides space between the reflector and first emission region that may be tuned for better emission region placement. A visual of the field squared 1418, or intensity, is also included to show placement of the emission regions relative to the antinodes of the field intensity.

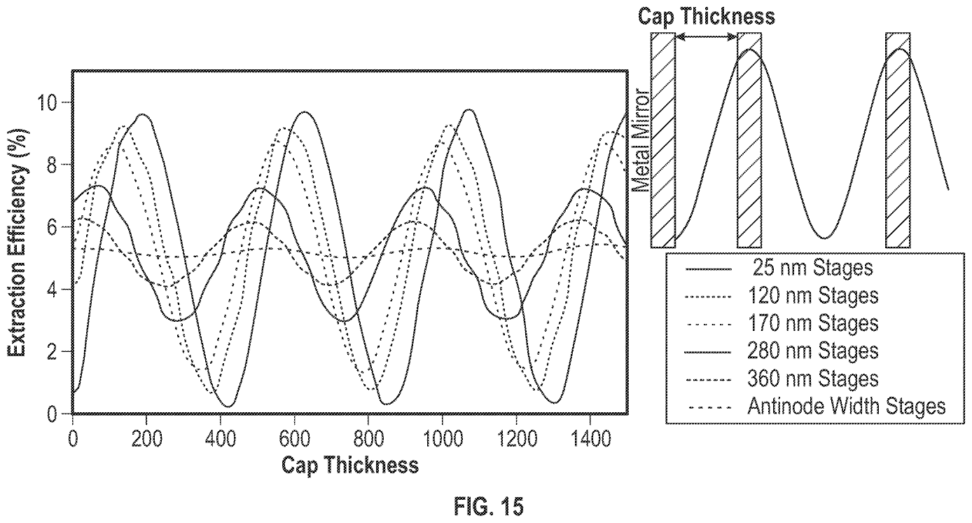

FIG. 15 shows the extraction efficiency from superlattice emission regions of variable thickness with an assumed mirror reflectivity of 0.93, where now the cap thickness is the distance from the mirror to the first emission region, as shown in the diagram. As the emission region becomes thicker, the extraction efficiency amplitude decreases as dipole positions are averaged over the oscillating standing electric field. For very thin emission regions, the averaged extraction efficiency can reach 10%, but then reduces to ~5.5% for emission regions with half wavelength thickness, i.e. continuous emission regions of total thickness 4λdesign. Extraction is still higher than the expectation for an isotropic emitter in a homogenous slab based on Snell's Law: ¼n² per side, or ½n² with a perfect mirror on one side. For n=3.7 and an 0.93 reflectivity mirror, the latter corresponds to 3.5%. This is expected because even with an “anti-node” factor of 1, light extraction is still enhanced from the microcavity extraction effect. Thus, light from the microcavity can be enhanced about a factor three compared to no microcavity enhancement in a half cavity, or nearly a factor of six compared to a device with no mirror.

The internal quantum efficiency (IQE) can also be enhanced by suppressing Auger recombination through thickening the emission region. Auger recombination refers to nonradiative recombination of an e-h pair by scattering of a third carrier into higher-lying bands, typically holes into higher valence bands. The internal quantum efficiency of e-h recombination can be represented in terms of the A, B, and C coefficients, with A associated with Shockley-Read-Hall nonradiative recombination, B the radiative coefficient, and C the Auger coefficient:

$$IQE = Bn / A + Bn + {Cn}^{2} \qquad ( 2 )$$

where n is volumetric carrier density. Note that the Auger rate increases with carrier density squared so long as carrier density is below degeneracy occupation, which is expected to be the case for the current densities considered here (in plots below, the maximum 500 A/cm² corresponds to 9×10¹⁷ cm⁻³ for a 100 nm thick sample at 300 K). For a fixed areal current density, the volumetric carrier density will decrease as the emission region gets thicker, thus reducing the Auger scattering rate and increasing the IQE.

Whereas Eq. (2) shows thicker emission regions reduce Auger by reducing carrier density n, it is expected that the thicker emission regions will reduce the microcavity enhancement by averaging over the standing wave, as indicated in FIG. 14. To see which factor is more important, the EQE as a function of emission region thickness including both cases where the microcavity effect is present versus not is plotted. First, to calculate the modified IQE due to the Purcell effect, note the radiative rate is increased by the Purcell factor:

$${R}_{r}^{′} = {F}_{P} Bn , \qquad ( 3 )$$

which then enhances the IQE as:

$$IQE = {F}_{p} Bn / A + {F}_{P} Bn + Cn2 . \qquad ( 4 )$$

To create plots of IQE for varying emission region thickness for several fixed current densities, convert carrier density to current density. Note areal current density depends on charge q, carrier density n, and drift velocity, which is replaced with recombination velocity v due to the carrier recombination serving as the limiting factor in the current:

$$J = qnv \qquad ( 5 )$$

where carrier recombination velocity is defined as:

$$v = t / τ = tR \qquad ( 6 )$$

with t emission region thickness, t carrier lifetime, and R recombination rate (=1/t):

$$R = A + FP Bn + {Cn}^{2} \qquad ( 7 )$$

such that:

$$J = qntR . \qquad ( 8 )$$

While microcavity modification to the IQE is minor due to the near-unity Purcell factor (FIG. 13), the microcavity extraction enhancement has a much greater impact on extraction efficiency, as shown in FIG. 15, which then affects the external quantum efficiency as:

$$EQE = η ( z ) IQE . \qquad ( 9 )$$

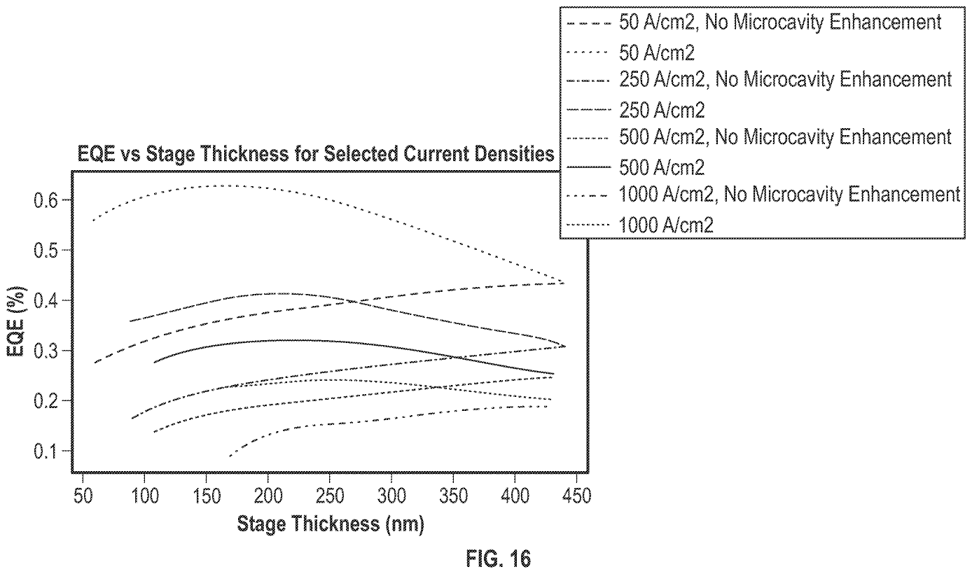

FIG. 16 is a plot of EQE at the design wavelength as a function of emission region thickness and compares EQE with the microcavity enhancement versus without. To calculate the EQE with microcavity effects using Eqs. (4) and (9), measured ABC coefficients for a similar W-superlattice were used³⁵, while MEEP was used to calculate η(z) and Fp(z). The ABC coefficients for room temperature material was used for room temperature simulations, and 77 K coefficients were used for 77 K simulations. EQE was averaged over emission region thickness. To turn off microcavity effects, the angle-resolved Purcell factor was set to one (see Eq. (1)), so still effectively includes trivial ~2× EQE enhancement from a back mirror.

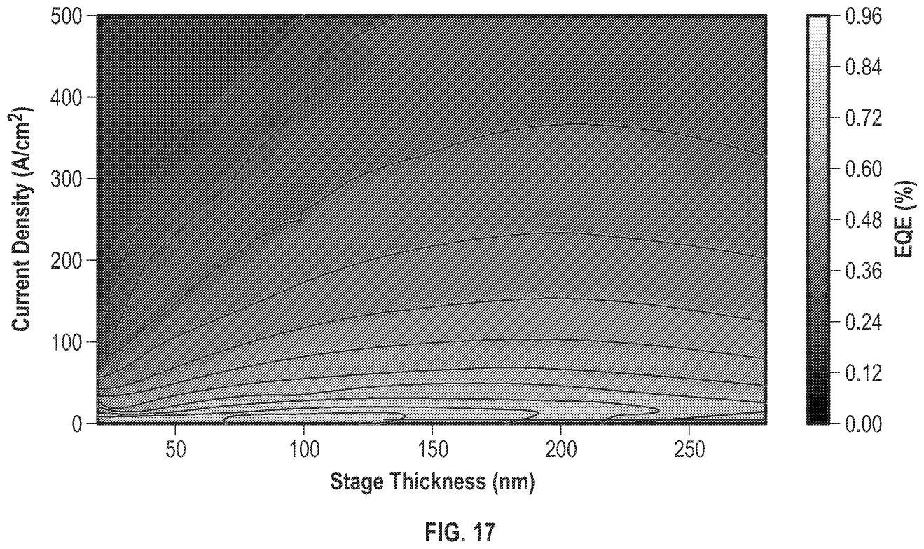

Without the microcavity, thicker emission regions lead to increasing EQE as Auger is more and more mitigated. However, with the microcavity, there is a significant drop in EQE for thicker emission regions due to reduced microcavity light extraction. Thus, while Auger scattering tends to increase EQE for thicker stages due to reduced carrier density, microcavity extraction favors thinner emission regions to better locate them at electric field antinodes, resulting in a peak EQE at intermediate thickness stages. To better visualize the full trade space, a heatmap was created, plotting current density versus stage thickness and having the colors represent our EQE values. Our heatmap is shown in FIG. 17. Note a wavelength averaged version of FIG. 16 has only minor differences (<10% change) because the half-cavity is relatively broadband (e.g., no Fabry-Perot).

### Experimental Results

Four mid-infrared LEDs with varying emission region thickness of 25 nm, 40 nm, 120 nm, and 280 nm were grown, fabricated, and tested. LEDs used a cascaded interband W-superlattice structure with eight W-superlattice emission regions in series in anti-nodes and separated by spacer layers which transport current. Rather than grow LEDs with only one emission region per antinode, some grouping of emission regions per antinode was done to keep the overall structure thinner. For the thinnest emission regions, 25 nm and 40 nm, four and three, respectively, were used per antinode. This was achieved with only a small penalty to extraction efficiency: the total group thickness was 175 nm/170 nm respectively, including tunnel junctions, reducing extraction efficiency from 10% to 8.5. %. For the intermediate 120 nm emission regions, two were grouped per antinode for a thickness of 265 nm (including the tunnel junction), and for 280 nm emission regions, only one per antinode, for an extraction efficiency of about 7.75% (see FIG. 15). The tunnel junctions are included between emission regions to allow carriers to tunnel from one region to the next, causing current to flow through each region in series rather than in parallel. This ensures all emission regions operate at the same current density. Once grown, these samples were quartered, and the cap of each quarter was thinned to a different degree. This allowed us to optimally center emission regions on antinodes.

TABLE I
Important thicknesses for the stack diagram shown in FIG. 18

| Emission Region | Tunnel Junction | Transport Layer |
|---|---|---|
| Thickness (ER) | Thickness (TJ) | Thickness^{a} |
| 25 nm (4 per antinode) | 25 nm | 246.7 nm |
| 40 nm (3 per antinode) | 25 nm | 252.1 nm, 284.6 nm |
| 120 nm (2 per antinode) | 25 nm | 160.8 nm |
| 280 nm (1 per antinode) | 25 nm | 146.8 nm |

^{a}The transport layer thickness denotes the thickness between each antinode. It may have multiple values depending on whether each antinode has an equal number of emission regions. For the 40 nm ER sample, the first transport region thickness listed corresponds to the transport layer closest to the cap.

The stack diagram 1800 of the 40 nm thick emission region structure is shown schematically in FIG. 18, with thicknesses of regions shown in Table 1. FIG. 18 includes an n-GaSb contact layer 1802, a planarized bottom contact 1804 in contact with the n-GaSb contact layer 1802, a stack 1806 (formed on the n-GaSb contact layer 1802), the stack 1806 including a first emission region 1808, a first tunnel junction 1810, a second emission region 1812, a second tunnel junction 1814, and an n-GaSb spacer layer 1816 (the stack 1806 repeated three times), a third emission region 1818, a third tunnel junction 1820 between the third emission region 1818 and a fourth emission region 1822, and a p-GaSb cap 1824 located between the fourth emission region 1822 and a top metal contact 1826. W-superlattices within a grouping were separated by n-AlGaAsSb/p-GaSb tunnel junctions of thickness 10 nm/15 nm, while groupings were separated by n-GaSb spacer layers, such as n-GaSb spacer layer 1816, to transport current. Mesas tested were 200 μm in diameter and square in shape. Ti/Pt/Au ohmic contacts were made to a top p-GaSb contact layer, also called the cap, which had variable thickness, and Pd/Ge/Au/Pt/Au ohmic contacts to a planarized bottom n-GaSb contact layer 3 μm thick. The top metal contact doubled as a reflective mirror. Samples were grown by molecular beam epitaxy and have no antireflection coating on the bottom surface, from which light is emitted. Samples were processed as identically as possible, flip-chipped onto Si fanout headers, and bonded to a leadless chip carrier. It is noted that the sample with 280 nm emission regions, one per antinode, was sufficiently thick to require a hard SiOx mask. The three thinner samples required only patterning the photoresist and etching. Once fabricated, the devices' light-current-voltage (LIV) characteristics were measured at room temperature to determine the output power and calculate the wallplug efficiency (WPE). LIV measurements were performed in the staring configuration with 50% duty cycle with a calibrated InSb detector, then integrated over the measured angular dependence to obtain the total upper hemisphere power.

WPE, or total power out/total power in, was used as a proxy for EQE for qualitative comparisons to the theory developed for EQE. WPE is directly proportional to EQE, though it also depends on other efficiencies:

$$ηwallplug = nEQE η ohmic η quantum defect . \qquad ( 10 )$$

Samples were found to all have the same resistance (10±2Ω) and hence ohmic efficiency within uncertainty. Since all samples use the same number of emission regions and tunnel junctions, and have the same mesa diode geometry, significant differences in the quantum defect are not expected. The quantum defect here refers to steps in the real space band structure where carriers lose energy. Ultimately, the WPE is also the most important figure of merit.

For a full cavity investigation, the stack diagram 1900 is as shown schematically in FIG. 19. The stack diagram includes a n-GaSb substrate 1902, a DBR 1904 located between the first n-GaSb layer 1906, and the n-GaSb substrate 1902, a first 3-stage W-Sl plus extra TJ 1908 located between the a second-GaSb layer 1910 and a second 3-stage W-SL plus extra TJ 1912, and a p-GaSB layer 1914 located between a metal contact 1916 and the second 3-stage W-SL plus extra TJ 1912. Planarized contact 1918 is in contact with the first n-GaSb layer 1906.

The full cavity device with two mirrors, one GaSb/AlSbAs and the other metal, is also called a resonant cavity LED or RCLED. Two structures were grown, each with 3×79 nm emission regions per antinode (two of them) and n-GaSb spacers between antinodes to keep the emission regions centered in the field antinodes. The structure was designed for resonance at 77 K, though operation to 300 K is still possible. One structure was fabricated with (“full cavity”) and the other without (“baseline”=half cavity) a bottom distributed Bragg reflector (DBR) to obtain a direct comparison between a half-cavity and a full cavity when investigating the device output. The reflector confined the cavity to be a 7/4-lambda cavity for the designed resonant wavelength. The cavity includes a sufficiently thick n-GaSb contact layer for lateral current transport from the metal contact. Devices were processed as described for the half-cavity devices, except mesas were 100 μm in diameter. As with the half-cavity devices, LIV measurements were performed using a 50% duty cycle and an InSb detector.

### Half-Cavity Mid-Infrared LEDs

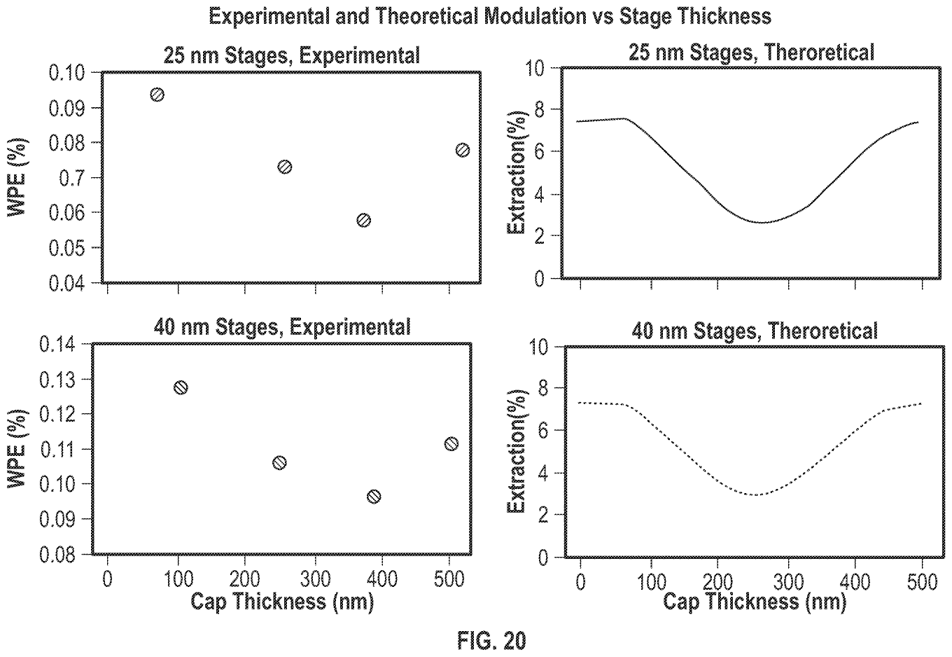

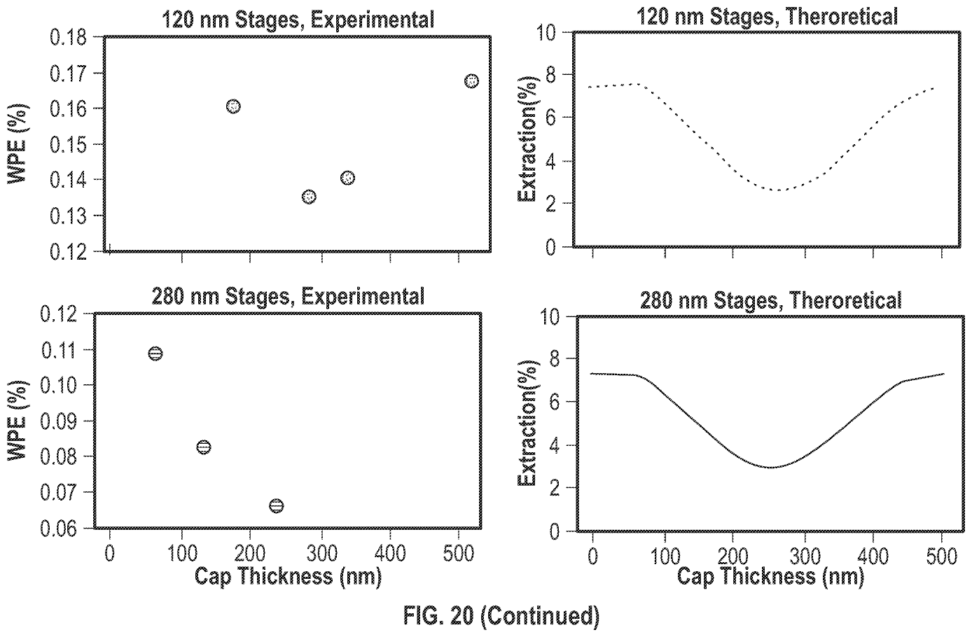

To ensure that emission regions were optimally centered on antinodes, given uncertainties of our material index and dispersion, the cap thickness was varied, or the distance from the metal mirror to the first emission region interface was varied. The resulting measured WPEs compared to the theoretical extraction efficiencies are shown in FIG. 20. The results show similar qualitative dependence on cap thickness.

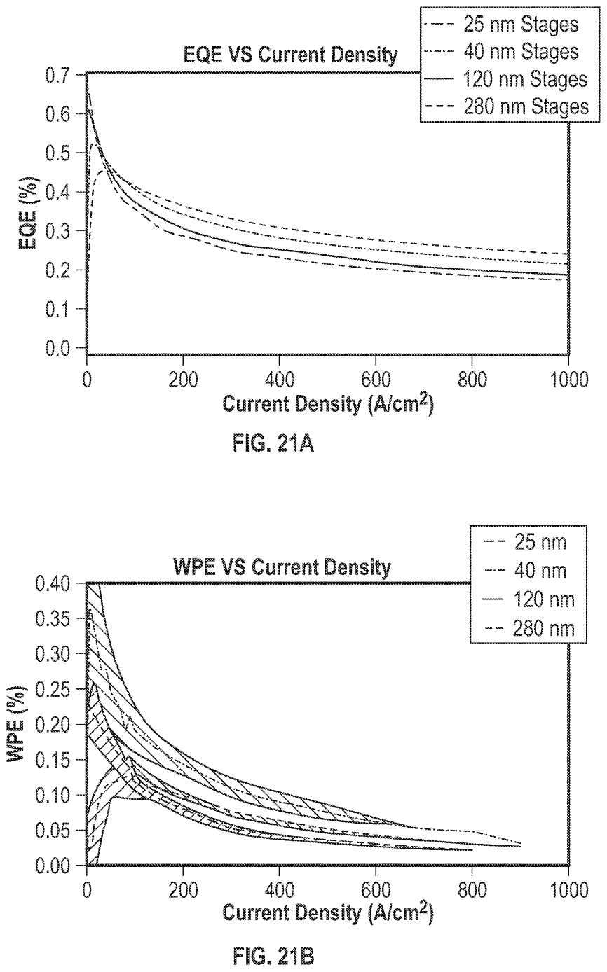

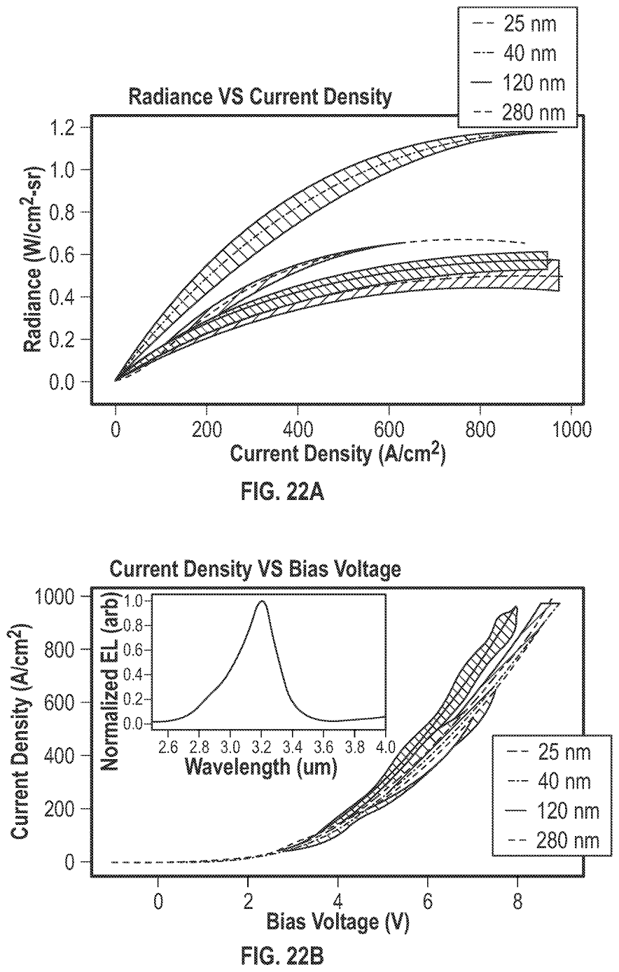

In FIG. 21, the theoretical EQE and the experimental WPE for the four experimental structures are qualitatively compared. Because WPE is integrated over all emission wavelengths, the EQE is averaged over emission wavelengths using a Gaussian weight with fit to the measured emission spectrum (see FIG. 22). Sample L-I and I-V measurements for the 280 nm emission region devices are shown in FIG. 22. WPE was calculated from the measured upper hemisphere power, determined from the measured radiance in the forward direction, then integrated over the upper hemisphere weighted by the measured angular distribution, which was found to be Lambertian, divided by the input power IV. The experimental data is an average of multiple devices with optimal cap thickness. The theoretical EQE shows that over most of the current density range, EQE steadily increases with stage thickness. This is in-line with the theoretical plot in FIG. 17 at the design wavelength with only one emission region per antinode; here the thickest stage gets a slight boost compared to the other devices because it has no grouping of stages per antinode. The experimental WPE plot shows an increase in WPE over most of the range with increasing emission region thickness for 25 nm, 40 nm, and 120 nm; however, there is unexpectedly a decrease for the 280 nm thick emission region. The theoretical EQE shows that at very low current densities, the 25 nm emission region devices can slightly outperform the thicker emission region devices. This was not observed in the experimental WPE data of devices.

### Full-Cavity Mid-Infrared LEDs

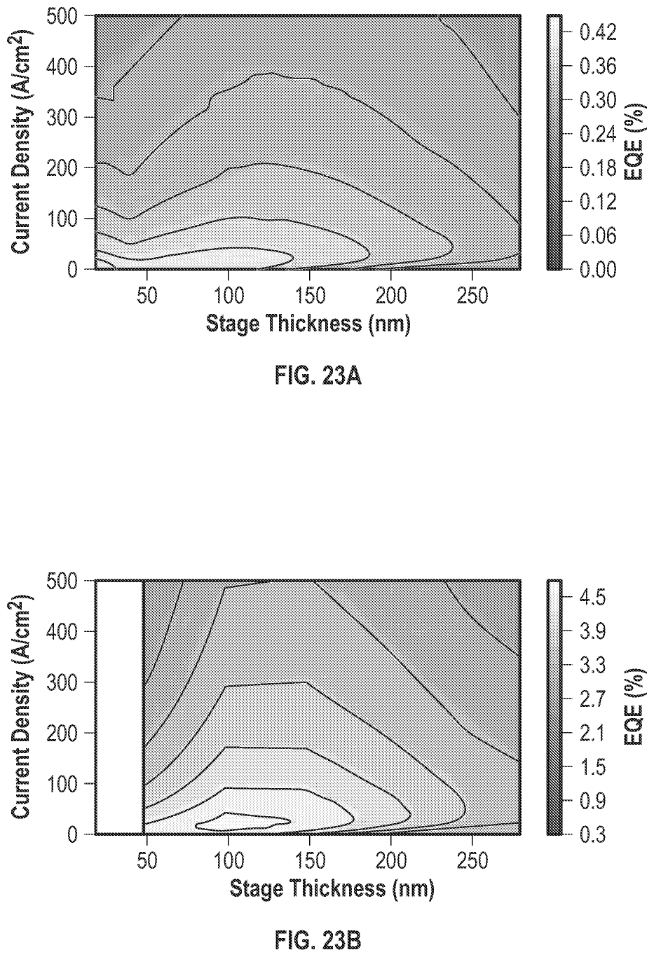

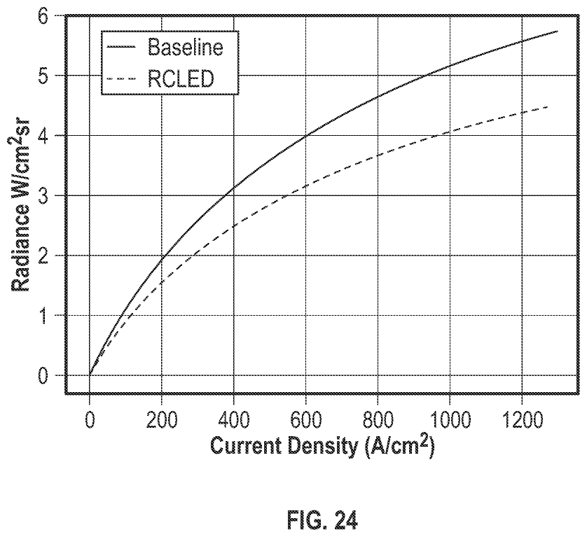

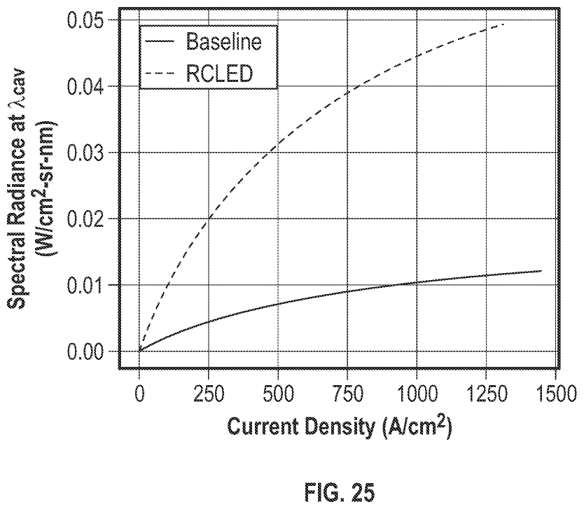

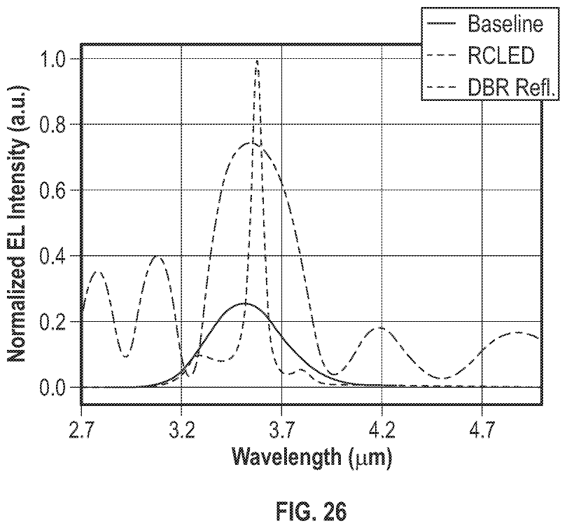

Initial results involved similar theoretical modeling of a full cavity to the baseline device. The EQE heatmaps for the resonant wavelength, shown in FIG. 23A and FIG. 23B, indicate that the enhancement is significant, with potential for up to ten times improvement in extraction efficiency and EQE at the design wavelength into the F/2 cone compared to a half-cavity (which itself was enhanced ~5× upper hemisphere compared to no microcavity enhancement-see FIG. 15, 16 discussion). FIG. 23B also indicate that the highest enhancement still occurs in W-superlattices of intermediate thickness. While the microcavity effect is stronger in a full microcavity compared to a half cavity, evidenced by the increased EQE enhancement, there is no shift toward thinner superlattices or quantum wells which microcavity enhancement favors. The experimental radiance measurements, shown in FIG. 24 at 77 K, show little change between the baseline and full cavity devices. Radiance, which is equal to WPE multiplied by the input power, is used here as a proxy for wavelength-integrated EQE, as other factors (ηohmic, ηquantum defect—see Eq. 10) are assumed to be similar between baseline and full cavity devices. However, measurements in FIG. 25 show that the spectral radiance of the full cavity device is 4 to 5 times that of the baseline device at the resonant wavelength of the cavity. The radiance is not enhanced by the full cavity, because while the cavity enhances extraction at the resonant wavelength, it strongly suppresses it at other wavelengths, as seen in FIG. 26. Because spectral radiance is radiance per unit wavelength, spectral radiance is strongly resonantly enhanced at the cavity wavelength. We speculate that the observed enhancement in spectral radiance is ~2× below the theory due to higher optical loss in the experimental cavity (e.g. metal mirror, background absorption) compared to the theoretical one (93% metal mirror, no background absorption).

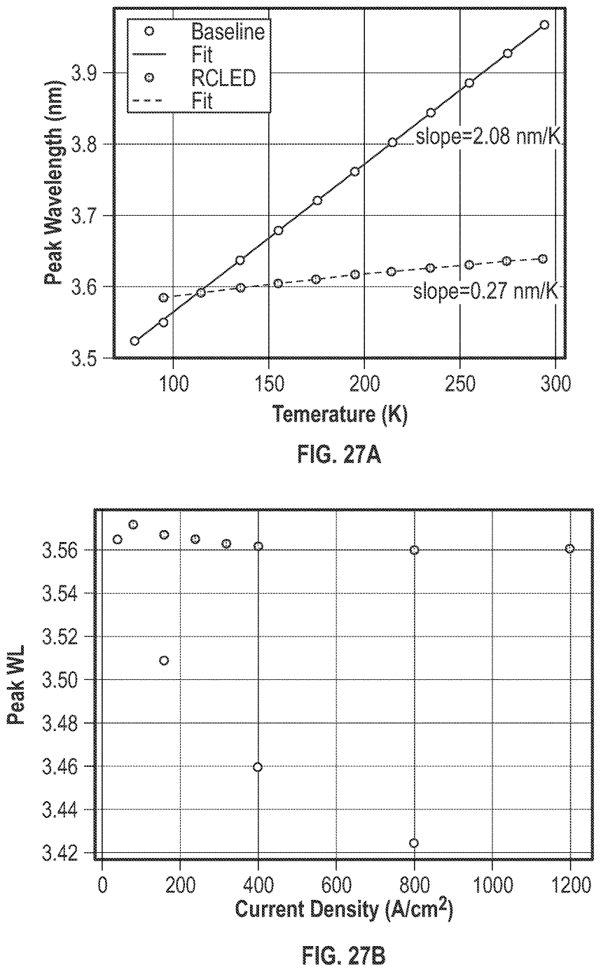

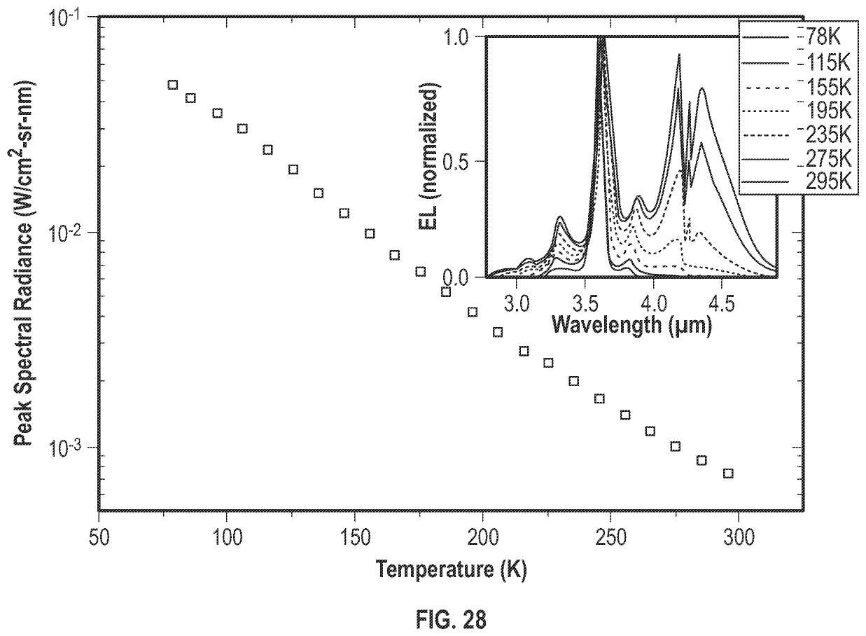

FIG. 27A shows the stability of the RCLED emission wavelength with temperature compared to the baseline device: only 0.27 nm/K versus 2.08 nm/K. FIG. 27B shows the nearly constant RCLED emission wavelength with current density compared to much higher shift of the baseline. Finally, FIG. 28A shows the nearly perfectly exponential decay of the peak spectral radiance with increasing temperature.

### DISCUSSION

This study was motivated by the question: which are more efficient, devices with thinner emission regions that take advantage of microcavity enhancement, or devices with thicker emission regions that allow for reduced Auger scattering through reduced carrier density?

In the case of putting only a single emission region per antinode (FIG. 17), thicker emission regions' EQE, theoretically, outperformed the thinner emission regions' EQE at every current density except when extremely low. This trend held for the more practical case of packing multiple emission regions per antinode (FIG. 21). Experimentally, note that that the WPE of devices with emission regions of increasing thickness perform better and better up to intermediate thickness. There is a reversal for devices with the thickest emission region, which was not expected, which is discuss further below. Thus, devices with intermediate superlattice thickness in half-cavities had wallplug efficiencies that outperformed thin superlattice (near the W-QW limit) emission regions at all current densities tested. Intermediate thicknesses achieve the best balance of reduced nonradiative Auger recombination while benefiting from microcavity enhancement.

Initially, it was expected the answer to the question of superlattice thickness to shift towards thinner emission regions for cavities with stronger microcavities, which favor thinner regions. However, the heat maps for the full cavity versus baseline (FIG. 23) shows that emission regions with intermediate thickness (150-225 nm) still had the highest EQEs over all current densities, with the thinnest and thickest superlattices doing the worst. While the testing conditions of the half and full cavity investigations do not make a direct comparison between the two possible, observing the trends of each still holds valuable insight into the larger picture.

The full cavity enhancements are significantly smaller than the reported resonant peak/integrated emission enhancement of 85×/13×, comparing a resonant microcavity device to a bulk InAsSb LED as the baseline. However, the irradiances/spectral irradiances identified here are >250× larger comparing at 77K, the design temperature, and still >50× at room temperature. Their enhancements are compared to a reference with no mirror, whereas the current reference, at least for the microcavity, was a half-cavity with one mirror. As the resonant wavelength half-cavity results were ~5× enhanced, comparison of the full cavity peak enhancement to no mirrors is estimated to be about 4-5×5=20-25×. Additionally, the maximum theoretical peak/integrated enhancements reported, is ~15×/3×. Finally, note that a metal mirror was used on the top, which allows for thinner devices (2×/4× for full/half cavity devices, respectively), eliminates injection through a DBR, and enables flip chipping for densely packed arrays.

An often-targeted goal for operation of infrared LEDs in gas sensors is brightest possible output with a maximum of 4V, 200 mA, which matches battery requirements and can lead to multi-year sensor lifetimes. The 200 μm half-cavity diameter devices here hit 4V and 200 mA (or 125 A/cm²) simultaneously with room temperature emission near the 3.3 μm methane absorption line, with efficiency of about 0.2%. Efficiencies approaching 0.4% with higher output power can be accessed by increasing the device size diameter, which allows operation at the same current, but lower current densities where efficiencies are higher (FIG. 21).

Finally, note the unexpected experimental results: the reduced WPE of the thickest superlattice half-cavity device (8×280 nm), and the smaller-than-expected WPE of the thinnest superlattice half-cavity device (8×25 nm) at the lowest current injection. A thicker superlattice is both thermally and electrically more resistive. Superlattices have been found to have very low perpendicular thermal conductivity due to the large number of interfaces present. Greater thermal resistance could lead to greater device heating. Greater electrical resistance would lead to higher ohmic losses; however, this can be ruled out, as all devices had a series resistance of about 10±2Ω within uncertainty as determined by the IV curves. Another possible cause is the longer etch times needed for the thickest structure in the harsh ICP-RIE dry etch chamber, which may have led to greater sidewall damage and material degradation. The four devices from thinnest to thickest had to be etched to depths of 0.7 μm, 1.3 μm, 1.8 μm, and 3.6 μm, respectively. However, note similar trends were found for variable superlattice thickness single stage structures previously: reduced performance was observed for the thickest emission regions (≥300 nm), which did not require a deep etch. To explain the results for the thinnest superlattice at the lowest current injection, note that in simulations, the same ABC coefficients were used for all superlattices, which were obtained from ultrafast measurements of a one-micron thick superlattice. It is possible that the ABC coefficients deviated in the thinnest case, especially a shorter SRH recombination coefficient A, which would lead to reduced efficiency at the lowest currents.

### CONCLUSION

To summarize, room temperature infrared LEDs at 3.2 μm in half-cavities with a top reflector provided by the metal contact operate best with W-superlattices of intermediate thickness-thick enough to reduce nonradiative Auger scattering, but thin enough to harness enhanced light extraction from microcavity enhancement. Half-cavity devices with superlattices of intermediate thickness (150-225 nm) outperformed the thinnest (20 nm, or 3 coupled W-quantum wells) at all input currents measured due to the importance of mitigating Auger recombination versus maximizing the microcavity effects. In some embodiments, the superlattices have a thickness of between 150 nm and 175 nm, between 175 nm and 200 nn, between 200 nm and 225 nm, and between 225 nm and 250 nm. Experimental half-cavity devices with peak WPE of about 0.4% were tested. Note also that because >90% of the light is still lost to total internal reflection, the light extraction and WPE could likely be improved by another factor of 2-3 times by thinning and roughening the backside, which would result in WPEs of ~1% at room temperature.

In 3.6 μm full cavity devices with two reflectors, the best superlattice emission region thickness for operation was still found in theory to be intermediate thickness regions in a similar regime as the baseline case. Experimentally, the tested devices exhibited 4 to 5 times increase in spectral radiance when comparing the full cavity to the baseline half-cavity (which in turn is about 5 times higher than a device with no mirrors). The experimental spectral radiances reported were found to be >250× larger than previously reported mid-infrared microcavity LEDs.

Both the half-cavity and full cavity devices make use of a top metal contact as one of the mirrors rather than a DBR, reducing the thickness of the structure, simplifying fabrication, and making them useful for flip chipping of dense arrays of devices.

In the preceding specification, various example embodiments have been described with reference to the accompanying drawings. It will, however, be evident that various modifications and changes can be made thereto, and additional embodiments may be implemented based on the principles of the present disclosure. The specification and drawings are accordingly to be regarded in an illustrative rather than restrictive sense.

For example, advantageous results still could be achieved if steps of the disclosed techniques were performed in a different order or if components in the disclosed systems were combined in a different manner or replaced or supplemented by other components. Other implementations are also within the scope of the following example claims.

1. A light emitting diode comprising:
a resonant cavity; and
a cascaded superlattice included in the resonant cavity.

2. The light emitting diode of claim 1, wherein the resonant cavity includes a mirror that also functions as a top contact.

3. The light emitting diode of claim 2, wherein the mirror includes a metal mirror.

4. The light emitting diode of claim 2, wherein the mirror contacts a thin p-type layer.

5. The light emitting diode of claim 1, wherein an n-type bottom contact layer is included inside the resonant cavity.

6. The light emitting diode of claim 5, wherein the bottom contact may be planarized to the top contact through a metal strap.

7. The light emitting diode of claim 1, wherein the cascaded superlattice includes more than one superlattice emission region, each superlattice emission region separated by a tunnel junction.

8. The light emitting diode of claim 1, wherein the resonant cavity includes a distributed Bragg reflector.

9. The light emitting diode of claim 8, wherein the Bragg reflector includes between about 1 and about 15 periods, includes GaSb/AlAsAb, and has a thickness of between about 1 micrometer and 20 micrometers.

10. The light emitting diode of claim 1, wherein the light emitting diode emits light in a narrowed waveband in the mid-infrared.

11. A gas sensor comprising:
the light emitting diode of claim 1.

12. The gas sensor of claim 11, wherein the gas sensor is configured to detect methane, carbon dioxide, or other molecule.

13. An apparatus comprising:
an array of light emitting devices formed on a substrate including the light emitting diode described in claim 1.

14. A light emitting diode comprising:
a resonant cavity including a mirror that also functions as a top contact and a distributed Bragg reflector, the resonant cavity having an antinode;
a cascaded W-superlattice included in the resonant cavity, the cascaded W-superlattice emitters including tunnel junctions between the W-superlattices, positioned at the antinode; and
an n-type bottom contact located inside the resonant cavity and included underneath the cascaded W-superlattices, the top contact and the n-type bottom contact may be planarized.

15. A light emitting diode stack including a second non-cavity peak that is independently controllable, the light emitting diode comprising:
an n-GaSb substrate;
a distributed Bragg reflector formed on the n-GaSb substrate;
a bottom contact formed on the distributed Bragg reflector;
a first color emitter formed on the bottom contact, the first color emitter including a cascaded W-superlattice emitter;
a middle contact formed on the first color emitter;
a second color emitter formed on the middle contact;
a top contact layer; and
a mirror that also functions as a top metal contact formed on the top contact layer.

16. The light emitting stack of claim 15, wherein the first color emitter is configured to emit a signal having a first wavelength and the second color emitter is configured to emit a signal having a second wavelength, and the second wavelength is longer than the first wavelength.

17. The light emitting diode stack of claim 16, wherein the light emitting diode stack includes a cavity and the second wavelength is resonant with the cavity.

18. The light emitting diode stack of claim 15, wherein the DBR has a bandwidth, wherein the light emitting diode stack includes a cavity and the first wavelength is not resonant with the cavity, and lies spectrally outside the bandwidth of the DBR.

19. The light emitting diode stack of claim 15, further comprising a field antinode, wherein the second color emitter overlaps with the field antinode.

20. The light emitting diode stack of claim 16, wherein the light emitting diode stack includes a cavity and the first wavelength is resonant with the cavity and the second wavelength is not resonant with the cavity.
